(19) United States
(12) Patent Application Publication
(10) Pub. No.: US 2016/0219687 A1
(43) Pub. Date: Jul. 28, 2016

(54) MICROPLASMA JET DEVICE, LAMINATED MICROPLASMA JET MODULE AND METHOD FOR MANUFACTURING MICROPLASMA JET DEVICE

(71) Applicant: AJOU UNIVERSITY INDUSTRY-ACADEMIC COOPERATION FOUNDATION, Suwon-si, Gyeonggi-do (KR)

(72) Inventors: Sang Sik YANG, Seoul (KR); Kang Il KIM, Jeonju-si (KR); Chang Min LEE, Seoul (KR)

(73) Assignee: AJOU UNIVERSITY INDUSTRY-ACADEMIC COOPERATION FOUNDATION, Suwon-si, Gyeonggi-do (KR)

(21) Appl. No.: 15/025,842

(22) PCT Filed: Oct. 1, 2014
(86) PCT No.: PCT/KR2014/009260

§ 371 Date: Mar. 29, 2016

(30) Foreign Application Priority Data
Oct. 2, 2013 (KR) 10-2013-0118027
Sep. 16, 2014 (KR) 10-2014-0122736

(51) Int. Cl. H05H 1/24; H01J 37/32

(52) U.S. Cl. CPC H05H 1/24; H01J 37/32532; H01J 37/32467

(57) ABSTRACT

A microplasma jet device, according to the present invention, comprises: a channel layer having a plurality of micro flow channels arranged in parallel so as to enable a gas for generating plasma to pass therethrough; a first insulating layer joined to one surface of the channel layer and having a first plasma generation electrode; and a second insulating layer joined to the other surface of the channel layer and having a second plasma generation electrode.

### TECHNICAL FIELD

The present invention relates to a plasma jet device, and more particularly, to a microplasma jet device capable of processing a large area, a laminated microplasma jet module, and a method of manufacturing the microplasma jet device.

### BACKGROUND ART

Plasma has been applied in various fields such as the semiconductor industry, the display industry, and for surface modification of materials. Recently, attempts to apply plasma to a bio-medical technology or surface processing of a material such as plastic or fiber have been made. However, in these applications, since an object material that should be treated by the plasma is sensitive to heat, a glow discharge, which is low-temperature plasma, should be used. Because glow discharge is very unstable at normal pressure, a glow-to-arc transition (GAT) in which the glow discharge is transitioned to an arc discharge, which is high-temperature plasma, is likely to occur.

The GAT occurs by heat generated while the plasma is generated, and research on microplasma generated by reducing the capacity of the plasma has been progressing as a method of preventing the GAT.

Conventionally, devices for generating microplasma cause discharge using needles or tubes which are mechanically processed. However, since there is a limit in reducing the size thereof through the mechanical processing and the plasma is generated using a single tube or needle, an area that can be processed at one time is limited.

### DISCLOSURE

### Technical Problem

The present invention is directed to providing a microplasma jet device capable of processing a larger area, a laminated microplasma jet module, and a method of manufacturing the microplasma jet device.

### Technical Solution

One aspect of the present invention provides a microplasma jet device including: a channel layer having a plurality of microfluidic channels arranged in parallel so as to enable a gas for generating plasma to pass therethrough; a first insulating layer bonded to one surface of the channel layer and in which a first plasma generation electrode is formed; and a second insulating layer bonded to another surface of the channel layer and in which a second plasma generation electrode is formed.

The microplasma jet device may further include a first substrate to which the first insulating layer is fixed and a second substrate to which the second insulating layer is fixed.

The channel layer may be made of a polymer-based material.

The polymer-based material may include polydimethylsiloxane (PDMS).

The first insulating layer and the second insulating layer may be made of a polymer-based material.

The first plasma generation electrode and the second plasma generation electrode may be formed by nickel plating.

The plurality of microfluidic channels may be insulated from the first plasma generation electrode and the second plasma generation electrode by the first insulating layer and the second insulating layer.

Another aspect of the present invention provides a microplasma jet module having a structure in which two or more of the microplasma jet devices are laminated by interposing a substrate therebetween.

Still another aspect of the present invention provides a method of manufacturing the microplasma jet device including: forming a mold by patterning a photosensitizer on one surface of a substrate to correspond to a plurality of microfluidic channels to be formed; forming a channel layer by pouring a polymer solution into the mold and curing the polymer solution; separating the channel layer from the mold; patterning a seed layer on one surface of a first substrate to correspond to a pattern of a first plasma generation electrode to be formed; forming the first plasma generation electrode by plating the seed layer; forming a first insulating layer by polymer coating a surface of the first substrate, in which the first plasma generation electrode is formed; patterning a seed layer on one surface of a second substrate to correspond to a pattern of a second plasma generation electrode to be formed; forming the second plasma generation electrode by plating the seed layer; forming a second insulating layer by polymer coating a surface of the second substrate, in which the second plasma generation electrode is formed; and bonding the first insulating layer, the channel layer, and the second insulating layer to each other.

The polymer solution may include a PDMS solution.

The patterning of the seed layer may include depositing titanium or gold.

The forming of the first plasma generation electrode or the forming of the second plasma generation electrode may include electroplating the seed layer with nickel.

### Advantageous Effects

According to the present invention, a microplasma jet device capable of processing a larger area, a laminated microplasma jet module, and a method of manufacturing the microplasma jet device are provided.

### DESCRIPTION OF DRAWINGS

FIG. 1 is a transparent perspective view illustrating a microplasma jet device according to an embodiment of the present invention.

FIG. 2 is a cross-sectional view illustrating a microplasma jet device according to an embodiment of the present invention.

FIG. 3 is a transparent exploded perspective view illustrating a microplasma jet device according to an embodiment of the present invention.

FIG. 4 is a view illustrating a method of manufacturing a microplasma jet device according to an embodiment of the present invention.

FIG. 5 is a transparent perspective view illustrating a laminated microplasma jet module according to an embodiment of the present invention.

FIG. 6 is a cross-sectional view illustrating a laminated microplasma jet module according to an embodiment of the present invention.

### MODES OF THE INVENTION

Hereinafter, exemplary embodiments of the invention will be described in detail with reference to the accompanying drawings. Like reference numerals in the drawings and descriptions denote like devices, and thus the description thereof will be omitted. Further, when it is determined that detailed explanations of related well-known functions or configurations unnecessarily obscure gist of the embodiments, the detailed description thereof will be omitted.

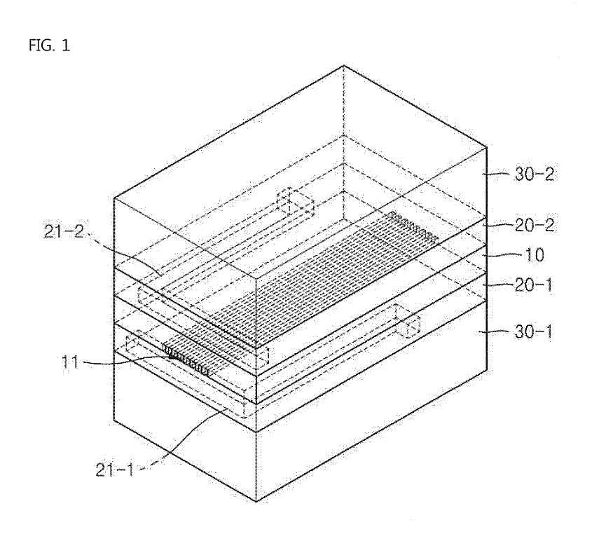

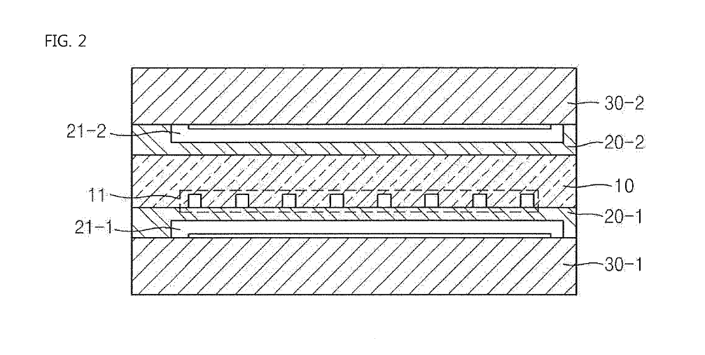

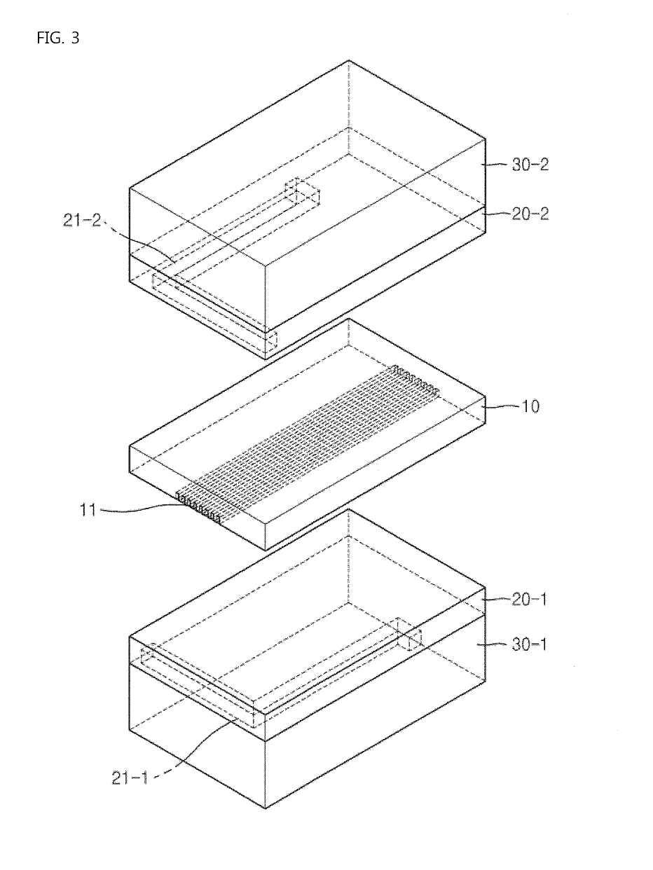

FIGS. 1 to 3 illustrate a structure of a microplasma jet device according to an embodiment of the present invention, where FIG. 1 is a transparent perspective view illustrating the microplasma jet device according to the present embodiment, FIG. 2 is a cross-sectional view illustrating the microplasma jet device according to the present embodiment, and FIG. 3 is a transparent exploded perspective view illustrating the microplasma jet device according to the present embodiment.

Referring to FIGS. 1 to 3, the microplasma jet device according to the present embodiment includes a channel layer 10 having a plurality of microfluidic channels 11 arranged in parallel so as to enable a gas for generating plasma to pass therethrough, a first insulating layer 20-1 which is bonded to one surface (a lower surface in the drawing) of the channel layer 10 and in which a first plasma generation electrode 21-1 is formed, a second insulating layer 20-2 which is bonded to another surface (an upper surface in the drawing) of the channel layer 10 and in which a second plasma generation electrode 21-2 is formed, a first substrate 30-1 to which the first insulating layer 20-1 is fixed, and a second substrate 30-2 to which the second insulating layer 20-2 is fixed.

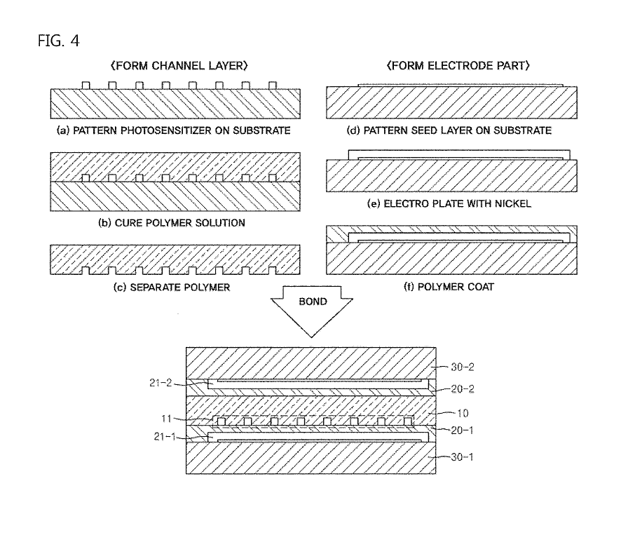

In the embodiment of the present invention, the channel layer 10 in which the plurality of microfluidic channels 11 are formed may be formed using a micromachining process. The plurality of microfluidic channels, each of which having a desired small size, may be formed using the micromachining process. The formation of the channel layer 10 will be described with reference to FIG. 4. The channel layer 10 is preferably made of a polymer-based material that can be used for insulating and can be processed as a mold, and here, the polymer-based material may include, for example, polydimethylsiloxane (PDMS).

Referring to FIG. 2, although it is illustrated that the number of the microfluidic channels 11 formed in a single channel layer 10 is, for example, 8, the present invention is not limited thereto, and the number thereof may be, for example, several to several tens. Further, the microfluidic channels 11 of a required number may be implemented according to an area to be processed.

A width of the single microfluidic channel may range from about 100 μm to 500 μm, and a height thereof may be about 100 μm. However, there is no specific limitation on a size of the microfluidic channel, and the size may range, for example, from several tens of μm to several hundreds of μm. A distance between the microfluidic channels may be two times the width, but there is no specific limitation thereon, and the distance may be several times or several hundred times the width of the channel.

Although it is illustrated that the microfluidic channels 11 are formed on a lower side of the channel layer 10 based on the drawings, the microfluidic channels 11 may be formed on an upper side of the channel layer 10. Referring to FIGS. 1 and 3, the microfluidic channels 11 at one side (a right side in the drawing) corresponds to inlets of the gas for generating plasma, and the microfluidic channels 11 at another side (a left side in the drawing) corresponds to outlets of the gas for generating plasma.

The first insulating layer 20-1 and the second insulating layer 20-2 serve to insulate the first plasma generation electrode 21-1 and the second plasma generation electrode 21-2 from the microfluidic channels 11 with the channel layer 10. Specifically, the microfluidic channels 11 are insulated from the first plasma generation electrode 21-1 by the first insulating layer 20-1, and are insulated from the second plasma generation electrode 21-2 by the channel layer 10 and the second insulating layer 20-2.

The first insulating layer 20-1 and the second insulating layer 20-2 may be made of a polymer-based material, and here, the polymer-based material may include, for example, PDMS.

The first plasma generation electrode 21-1 and the second plasma generation electrode 21-2 may be respectively formed in the first insulating layer 20-1 and the second insulating layer 20-2, and may be formed in a predetermined pattern to be suitable for the generation of plasma. For example, the patterns of the first plasma generation electrode 21-1 and the second plasma generation electrode 21-2 may be formed to face each other at portions corresponding to the outlets of the microfluidic channels 11.

The first plasma generation electrode 21-1 and the second plasma generation electrode 21-2 may be respectively formed on surfaces opposite to surfaces in which the first insulating layer 20-1 and the second insulating layer 20-2 are bonded to the channel layer 10 so as to be insulated from the microfluidic channels 11 by the first insulating layer 20-1 and the second insulating layer 20-2. The first plasma generation electrode 21-1 and the second plasma generation electrode 21-2 may be formed, for example, by nickel plating.

The first substrate 30-1 and the second substrate 30-2 respectively fix the first insulating layer 20-1 and the second insulating layer 20-2, respectively fix the first plasma generation electrode 21-1 and the second plasma generation electrode 21-2, and also serve to respectively insulate the first plasma generation electrode 21-1 and the second plasma generation electrode 21-2 from the outside. The first substrate 30-1 and the second substrate 30-2 may be, for example, a glass substrate.

An operating principle of the microplasma jet device according to the present embodiment is as follows. The gas for generating plasma injected into the inlets of the microfluidic channels 11 is ionized by an electric field formed by the first plasma generation electrode 21-1 and the second plasma generation electrode 21-2 while passing through the microfluidic channels 11, and thus plasma is generated. The generated plasma is pushed by the gas entering the microfluidic channels 11, and is jetted through the outlets of the microfluidic channels 11.

FIG. 4 is a view illustrating a method of manufacturing a microplasma jet device according to an embodiment of the present invention.

The method of manufacturing the microplasma jet device according to the present embodiment mainly includes forming a channel layer 10 in which microfluidic channels 11 are formed, forming an insulating layer 20-1 or 20-2, in which a plasma generation electrode 21-1 or 21-2 are formed, and a substrate 30-1 or 30-2 (hereinafter, referred to as an electrode part), and bonding the channel layer 10 to the electrode parts.

The forming of the channel layer 10 is as follows. A mold is formed by patterning a photosensitizer on one surface of a substrate (for example, a silicon substrate) so as to correspond to a shape of each of the microfluidic channels to be formed (a). Then, a channel layer is formed by pouring a polymer solution into the formed mold and curing the polymer solution (b). Here, the polymer solution may include a PDMS solution. Next, the channel layer in which the microfluidic channels are formed is obtained by separating the cured polymer from the mold (c).

The forming of the electrode parts is as follows. Since an electrode part bonded to a top of the channel layer 10 and an electrode part bonded to a bottom of the channel layer 10 are typically symmetrical and processes of forming the electrode parts are substantially the same, only the process of forming a single electrode part will be described.

A seed layer is patterned on one surface of a substrate (for example, the glass substrate) so as to correspond to a pattern of each of the plasma generation electrodes to be formed (d). Here, the seed layer may be formed by, for example, depositing titanium or gold using an electroplating method, and for example, a photosensitizer and an etching solution may be used in the patterning of the seed layer. Next, the plasma generation electrodes are formed by plating the patterned seed layer (e). Here, the plasma generation electrodes may be formed by electroplating the seed layer with nickel. Next, an insulating layer is formed by polymer coating a surface of the substrate, in which the plasma generation electrodes are formed, so that all of the plasma generation electrodes are covered (f). Through the above-described processes such as (d), (e), and (f), the electrode part including the substrate 30-1 or 30-2, the plasma generation electrode 21-1 or 21-2, and the insulating layer 20-1 or 20-2 is formed.

Then, as the channel layer and the electrode parts which are formed in the above-described manner are bonded to each other, the microplasma jet device according to the embodiment of the present invention is completed. That is, the first insulating layer 20-1 is bonded to a lower surface of the channel layer 10, and the second insulating layer 20-2 is bonded to an upper surface of the channel layer 10. In this case, as the channel layer 10 and the insulating layers 20-1 and 20-2 are to be in close contact with each other and are heated to a determined temperature (for example, about 1500° C.) for a predetermined time (for example, about 15 minutes), the channel layer 10 and the insulating layers 20-1 and 20-2 may be bonded to each other.

A microplasma jet module having a laminated structure may be formed by stacking two or more of the microplasma jet devices according to the embodiment of the present. For example, this is because the channel layer and the insulating layer, which are made of a polymer-based material, are easily bonded to each other. According to the embodiment of the present invention, since a size of the module may be increased by as much as desired by stacking the microplasma jet devices, a microplasma jet module that can process as large an area as desired at one time may be implemented.

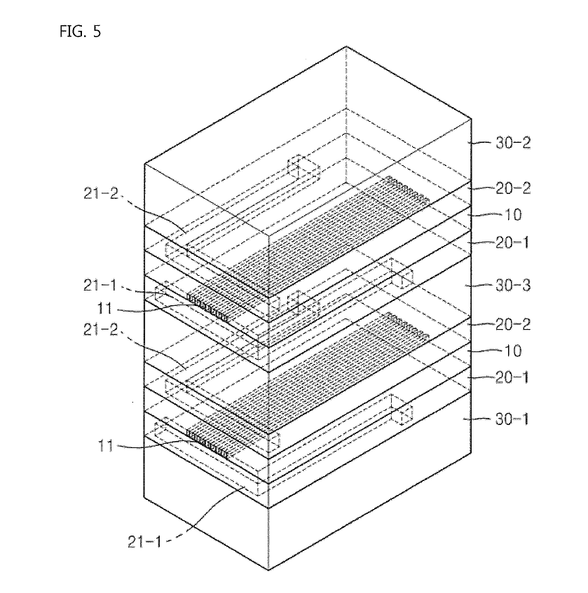

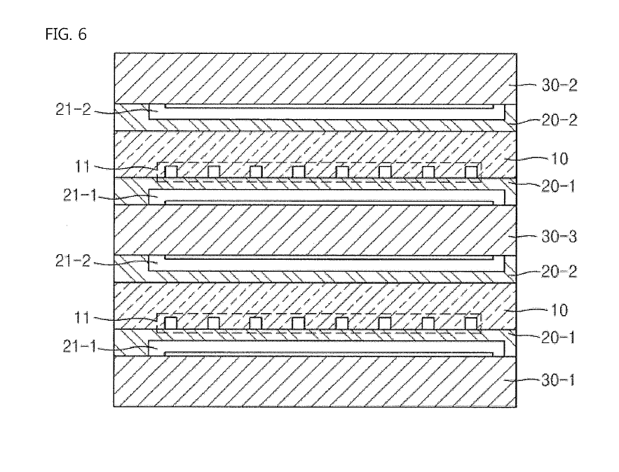

FIGS. 5 and 6 illustrate a structure of a laminated microplasma jet module according to an embodiment of the present invention, where FIG. 5 is a transparent perspective view illustrating the laminated microplasma jet module according to the present embodiment and FIG. 6 is a cross-sectional view illustrating the laminated microplasma jet module according to the present embodiment.

Referring to FIGS. 5 and 6, the laminated microplasma jet module according to the present embodiment includes channel layers 10 having a plurality of microfluidic channels 11 arranged in parallel so as to enable a gas for generating plasma to pass therethrough, two microplasma jet devices each including a first insulating layer 20-1 which is bonded to one surface (a lower surface in the drawing) of the channel layer 10 and in which a first plasma generation electrode 21-1 is formed and a second insulating layer 20-2 which is bonded to another surface (an upper surface in the drawing) of the channel layer 10 and in which a second plasma generation electrode 21-2 is formed, wherein the two microplasma jet devices are laminated by interposing an intermediate substrate 30-3 therebetween, a first substrate 30-1 to which the first insulating layer 20-1 of a lower microplasma jet device is fixed, and a second substrate 30-2 to which the second insulating layer 20-2 of an upper microplasma jet device is fixed.

In the present embodiment, although two of the microplasma jet devices being laminated is described as an example, two or more of the microplasma jet devices may be laminated.

A process of forming the laminated microplasma jet module of FIGS. 5 and 6 is as follows.

Two channel layers 10 may be formed through the above-described process of forming the channel layer.

Further, through the above-described process of forming electrode part, two electrode parts, that is, a lower electrode part including the first substrate 30-1, the first plasma generation electrode 21-1, and the first insulating layer 20-1, and an upper electrode part including the second substrate 30-2, the second plasma generation electrode 21-2, and the second insulating layer 20-2, may be formed.

Referring to FIGS. 5 and 6, the plasma generation electrodes 21-1 and 21-2 and the insulating layers 20-1 and 20-2 are respectively formed on both side surfaces of the intermediate substrate 30-3. Therefore, an intermediate electrode part including the intermediate substrate 30-3 and the plasma generation electrodes 21-1 and 21-2 and the insulating layers 20-1 and 20-2 which are formed on the both side surfaces of the intermediate substrate 30-3 may be formed through a process similar to the above-described process of forming the electrode part. Since the above-described process of forming the electrode part is a process of forming the plasma generation electrode and the insulating layer on only one side surface of the substrate, the intermediate electrode part may be formed through a process in which the above-described process of forming the electrode part is slightly modified, that is, through a process of respectively forming the plasma generation electrode and the insulating layer on both side surfaces of the substrate.

When the two channel layers, the upper and lower electrode parts, and the intermediate electrode part, which are formed in this manner, are bonded in an order illustrated in FIGS. 5 and 6, the laminated microplasma jet module according to the present embodiment is completed.

While the present invention has been particularly described with reference to exemplary embodiments, it should be understood by those skilled in the art that various changes in form and details may be made without departing from the spirit and scope of the present invention. Therefore, the exemplary embodiments should be considered in a descriptive sense only and not for purposes of limitation. The scope of the invention is defined not by the detailed description of the invention but by the appended claims, and encompasses all modifications and equivalents that fall within the scope of the appended claims and are construed as being included in the present invention.

1. A microplasma jet device, comprising:
a channel layer having a plurality of microfluidic channels arranged in parallel so as to enable a gas for generating plasma to pass therethrough, are formed;
a first insulating layer bonded to one surface of the channel layer and in which a first plasma generation electrode is formed; and
a second insulating layer bonded to another surface of the channel layer and in which a second plasma generation electrode is formed.

2. The device of claim 1, further comprising:
a first substrate to which the first insulating layer is fixed; and
a second substrate to which the second insulating layer is fixed.

3. The device of claim 1, wherein the channel layer is made of a polymer-based material.

4. The device of claim 3, wherein the polymer-based material includes polydimethylsiloxane (PDMS).

5. The device of claim 1, wherein the first insulating layer and the second insulating layer is made of a polymer-based material.

6. The device of claim 1, wherein the first plasma generation electrode and the second plasma generation electrode is formed by nickel plating.

7. The device of claim 1, wherein the plurality of microfluidic channels are insulated from the first plasma generation electrode and the second plasma generation electrode by the first insulating layer and the second insulating layer.

8. A microplasma jet module having a structure in which two or more of the microplasma jet devices according to claim 1 are laminated by interposing a substrate therebetween.

9. A method of manufacturing a microplasma jet device, the method comprising:
forming a mold by patterning a photosensitizer on one surface of a substrate to correspond to a plurality of microfluidic channels to be formed;
forming a channel layer by pouring a polymer solution into the mold and curing the polymer solution;
separating the channel layer from the mold;
patterning a seed layer on one surface of a first substrate to correspond to a pattern of a first plasma generation electrode to be formed;
forming the first plasma generation electrode by plating the seed layer;
forming a first insulating layer by polymer coating a surface of the first substrate, in which the first plasma generation electrode is formed;
patterning a seed layer on one surface of a second substrate to correspond to a pattern of a second plasma generation electrode to be formed;
forming the second plasma generation electrode by plating the seed layer;
forming a second insulating layer by polymer coating a surface of the second substrate, in which the second plasma generation electrode is formed; and
bonding the first insulating layer, the channel layer, and the second insulating layer to each other.

10. The method of claim 9, wherein the polymer solution includes a PDMS solution.

11. The method of claim 9, wherein the patterning of the seed layer includes depositing titanium or gold.

12. The method of claim 9, wherein the forming of the first plasma generation electrode or the forming of the second plasma generation electrode includes electroplating the seed layer with nickel.
